(19) United States
(12) Patent Application Publication
(10) Pub. No.: US 2025/0378777 A1
(43) Pub. Date: Dec. 11, 2025

(54) ELECTRONIC DEVICE AND METHOD FOR OPERATING ELECTRONIC DEVICE

(71) Applicant: Samsung Electronics Co., Ltd., Suwon-si (KR)

(72) Inventors: Minjae YOO, Suwon-si, Gyeonggi-do (KR); Youngmin KIM, Suwon-si (KR); Jungsoo LEE, Suwon-si (KR)

(21) Appl. No.: 19/301,186

(22) Filed: Aug. 15, 2025

Related U.S. Application Data
(63) Continuation of application No. PCT/KR2024/002041, filed on Feb. 13, 2024.

(30) Foreign Application Priority Data
Feb. 16, 2023 (KR) 10-2023-0020814

(51) Int. Cl. G09G 3/20

(52) U.S. Cl. CPC G09G 3/2096; G09G 2330/045; G09G 2330/06

(57) ABSTRACT

An electronic device may include a first substrate, a memory storing at least one instruction and disposed on the first substrate, at least one processor configured to execute the at least one instruction stored in the memory and disposed on the first substrate, and a second substrate on which a conductive line is disposed, wherein the at least one processor and the conductive line are electrically connected to each other, and the at least one processor is further configured to provide a compensation signal to the conductive line so that a magnetic field for reducing electro-magnetic interference (EMI) noise generated in the first substrate is induced from the conductive line.

### CROSS-REFERENCE TO RELATED APPLICATIONS

This application is a continuation application of International Application No. PCT/KR2024/002041, filed on Feb. 13, 2024, in the Korean Intellectual Property Receiving Office, and claiming priority to Korean Patent Application No. 10-2023-0020814 filed Feb. 16, 2023, the disclosures of which are all hereby incorporated by reference herein in their entireties.

### TECHNICAL FIELD

Various example embodiments relate to an electronic device and/or an operating method of the same, and for example, to an electronic device for reducing electro-magnetic interference (EMI) noise, and/or an operating method of the electronic device.

### BACKGROUND ART

Recently, with the development of technology, functions provided by an electronic device have become diverse and complex. In an electronic device for providing an image, a resolution of the provided image is increasing to increase visibility for a user. In addition, a driving frequency at which the electronic device provides an image is also increasing.

As the electronic device operates to provide various functions, a driving frequency of a processor that controls the electronic device is also increasing. Accordingly, electro-magnetic interference (EMI) noise generated in a driving circuit included in the electronic device may be generated and the magnitude of the EMI noise may increase, thereby affecting operations of the electronic device. Thus, various technologies for reducing EMI noise generated when an electronic device operates are being developed.

### SUMMARY

An electronic device according to an example embodiment may include a first substrate. The electronic device may include a memory storing at least one instruction and disposed on (directly or indirectly) the first substrate. The electronic device may include at least one processor, comprising processing circuitry, individually and/or collectively configured to execute the at least one instruction stored in the memory and disposed on, directly or indirectly, the first substrate. The electronic device may include a second substrate on which a conductive line is disposed directly or indirectly. The at least one processor and the conductive line may be electrically connected, directly or indirectly, to each other. The at least one processor may be individually and/or collectively configured to provide a compensation signal to the conductive line so that a magnetic field for reducing electro-magnetic interference (EMI) noise generated in the first substrate is induced from the conductive line.

An example embodiment provides an operating method of an electronic device. The electronic device may include a first substrate on which at least one processor is directly or indirectly disposed. The electronic device may include a second substrate directly or indirectly on which a conductive line electrically connected, directly or indirectly, to the at least one processor is disposed. The operating method may include providing a compensation signal to the conductive line so that a magnetic field for reducing electro-magnetic interference (EMI) noise generated in the first substrate is induced from the conductive line.

An example embodiment provides an electronic device for displaying an image. The electronic device may include a display displaying the image. The electronic device may include a first substrate on which a memory storing at least one instruction and at least one processor configured to execute the at least one instruction stored in the memory are disposed. The electronic device may include a second substrate spaced apart from the first substrate and on which a conductive line is disposed. The at least one processor and the conductive line may be electrically connected to each other. The at least one processor may be further configured to control the display to display the image. The at least one processor may be further configured to provide a compensation signal to the conductive line so that a magnetic field for reducing electro-magnetic interference (EMI) noise generated in the first substrate is induced from the conductive line.

### BRIEF DESCRIPTION OF DRAWINGS

The present disclosure may be understood by a combination of the following detailed descriptions and accompanying drawings, and reference numerals refer to structural elements.

FIG. 1 is a diagram for describing an electronic device according to an example embodiment.

FIG. 2 is a block diagram for describing a configuration of an electronic device, according to an example embodiment.

FIG. 3 is a diagram for describing an operation of an electronic device, according to an example embodiment.

FIG. 4A is a diagram for describing a conductive connection member according to an example embodiment.

FIG. 4B is a diagram for describing a conductive connection member according to an example embodiment.

FIG. 5A is a flowchart for describing an operation in which an electronic device determines a magnitude and a direction of a compensation signal, according to an example embodiment.

FIG. 5B is a flowchart for describing an operation in which an electronic device changes at least one of a magnitude and a direction of a compensation signal, according to an example embodiment.

FIG. 6A is a diagram for describing a direction of a magnetic field induced from a conductive line, according to an arrangement of the conductive line and a direction of a compensation signal, according to an example embodiment.

FIG. 6B is a diagram for describing a direction of a magnetic field induced from a conductive line, according to an arrangement of the conductive line and a direction of a compensation signal, according to an example embodiment.

FIG. 7A is a diagram for describing a degree of reduction of electro-magnetic interference (EMI) noise according to a magnitude of a compensation signal, according to an example embodiment.

FIG. 7B is a diagram for describing a degree of reduction of EMI noise according to a magnitude of a compensation signal, according to an example embodiment.

FIG. 7C is a diagram for describing a degree of reduction of EMI noise according to a magnitude of a compensation signal, according to an example embodiment.

### DETAILED DESCRIPTION

The terms used in the present disclosure will be briefly defined, and an example embodiment will be described in detail.

All terms including descriptive or technical terms which are used herein should be construed as having meanings that are obvious to one of ordinary skill in the art. However, the terms may have different meanings according to the intention of one of ordinary skill in the art, precedent cases, or the appearance of new technologies. Also, some terms may be arbitrarily selected by the applicant, and in this case, the meaning of the selected terms will be described in detail in the detailed description of an example embodiment. Thus, the terms used herein have to be defined based on the meaning of the terms together with the description throughout the specification.

An expression used in the singular may encompass the expression in the plural, unless it has a clearly different meaning in the context. Terms used herein, including technical or scientific terms, may have the same meaning as commonly understood by one of ordinary skill in the art described in the present specification.

Throughout the present disclosure, when a part “includes” or “comprises” an element, unless there is a particular description contrary thereto, the part may further include other elements, rather than excluding the other elements. In addition, terms such as “unit (-er/or)” and “module” described in the present disclosure denote a unit that processes at least one function or operation, which may be implemented in hardware or software, or implemented in a combination of hardware and software. Thus, each “module” herein may comprise circuitry.

The expression “configured to” used in the present disclosure may be replaced by, for example, suitable for”, “having the capacity to”, “designed to”, “adapted to”, made to”, or “capable of”, according to situations. The expression “configured to” may not necessarily indicate “specifically designed to” in terms of hardware. Instead, in a certain situation, the expression “system configured to” may indicate that the system may be “capable of” together with another device or components. For example, “a processor configured to perform A, B, and C” may indicate a dedicated processor (e.g., an embedded processor) for performing corresponding operations or indicate a generic-purpose processor (e.g., a central processing unit (CPU) or an application processor) performing the corresponding operations by executing one or more software programs stored in a memory.

Also, in the present disclosure, it will be understood that when one element is “connected” or “coupled” to another element, the elements may be directly connected or coupled to each other, but may alternatively be connected or coupled to each other with an intervening element therebetween, unless specified otherwise.

Hereinafter, embodiments of the present disclosure will be described in detail with reference to the accompanying drawings such that one of ordinary skill in the art may casily implement the embodiments of the present disclosure. However, an example embodiment may be implemented in various different forms and is not limited to an embodiment described herein. Also, in the drawings, parts irrelevant to the description are omitted in order to clearly describe an example embodiment, and like reference numerals designate like elements throughout the specification.

Hereinafter, embodiments of the present disclosure will be described in detail with reference to accompanying drawings.

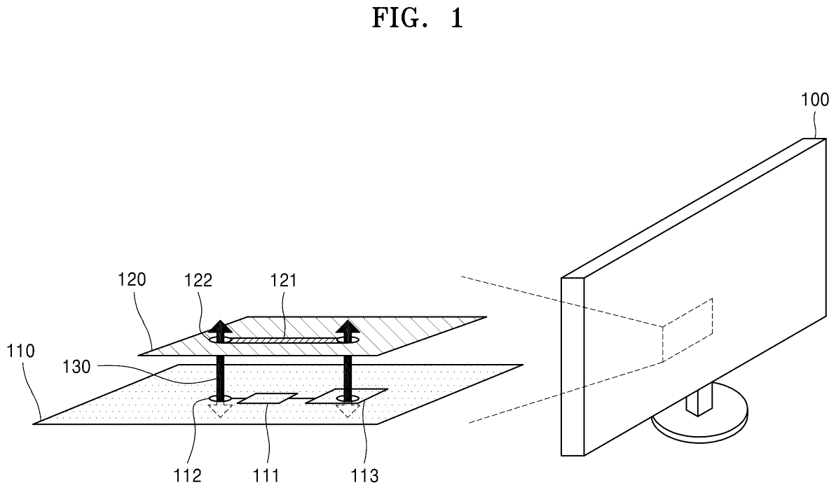

FIG. 1 is a diagram for describing an electronic device according to an example embodiment.

Referring to FIG. 1, according to an embodiment, an electronic device 100 may be an electronic device for providing an image to a user. The electronic device 100 may include a display displaying the image. In FIG. 1, the electronic device 100 is illustrated as a television displaying an image. However, the present disclosure is not limited thereto. The electronic device 100 may be implemented as any type of electronic device, such as a mobile device, a smartphone, a laptop computer, a desktop computer, a tablet personal computer (PC), or a wearable device. Hereinafter, for convenience of description, the electronic device 100 is described as a television displaying an image.

In an embodiment, the electronic device 100 may include a first substrate 110 and a second substrate 120. The electronic device 100 may include at least one processor 111 configured to control operations of the electronic device 100. In an embodiment, the at least one processor 111 may be disposed on the first substrate 110. In an embodiment, a conductive line 121 may be disposed on the second substrate 120. “Disposed on” as used herein covers both disposed directly and/or indirectly on.

In an embodiment, the at least one processor 111 and the conductive line 121 may be electrically connected, directly or indirectly, to each other. In an embodiment, the at least one processor 111 and the conductive line 121 may be electrically connected to each other through at least a conductive connection member 130. The conductive line 121 may be electrically connected, directly or indirectly, to the at least one processor 111 disposed on the first substrate 110 and a reference voltage electrode 113 of the first substrate 110, through the conductive connection member 130. In an embodiment, electric potential of the reference voltage electrode 113 may be a voltage serving as a ground for the first substrate 110.

In an embodiment, the conductive line 121, the at least one processor 111, and the reference voltage electrode 113 of the first substrate 110 may be electrically connected, directly or indirectly, to each other and form a closed circuit. In an embodiment, the conductive line 121, the conductive connection member 130, the at least one processor 111, and the reference voltage electrode 113 of the first substrate 110 may be electrically connected to each other and form a closed circuit.

In an embodiment, the first substrate 110 and the second substrate 120 may be spaced apart from each other. The conductive connection member 130 may connect the first substrate 110 and the second substrate 120 to each other through a first hole 112 included in the first substrate 110 and a second hole 122 included in the second substrate 120. A distance between the first substrate 110 and the second substrate 120 may be maintained by the conductive connection member 130. However, the present disclosure is not limited thereto, and even when the first substrate 110 and the second substrate 120 are connected to each other by the conductive connection member 130, the distance between the first substrate 110 and the second substrate 120 may change.

In an embodiment, the first hole 112 may include a hole electrically connected to the at least one processor 111 and a hole electrically connected to the reference voltage electrode 113 of the first substrate 110. The second hole 122 may be electrically connected to the conductive line 121.

In an embodiment, the conductive connection member 130 may electrically connect the at least one processor 111 and the conductive line 121 to each other through the first hole 112 and the second hole 122. The conductive connection member 130 may electrically connect the at least one processor 111, the conductive line 121, and the reference voltage electrode 113 of the first substrate 110 to each other through the first hole 112 and the second hole 122 to form a closed circuit.

In an embodiment, in FIG. 1, the first substrate 110 and the second substrate 120 are located at a center portion of the electronic device 100. However, the present disclosure is not limited thereto, and the first substrate 110 and the second substrate 120 may be located at an upper portion or a lower portion of the electronic device 100.

In an embodiment, in FIG. 1, the first substrate 110 and the second substrate 120 each have a rectangular shape. However, the present disclosure is not limited thereto, and the first substrate 110 and the second substrate 120 may have a shape in which at least one side is round. Also, in FIG. 1, a size of the second substrate 120 is smaller than a size of the first substrate 110, but the present disclosure is not limited thereto. In an embodiment, the size of the second substrate 120 may be the same as the size of the first substrate 110 or may be greater than the size of the first substrate 110.

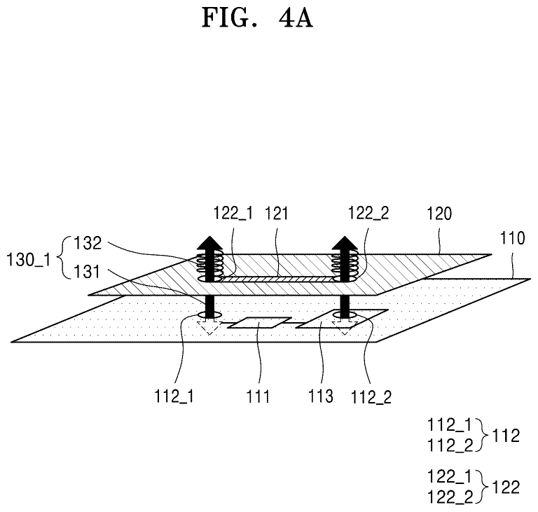

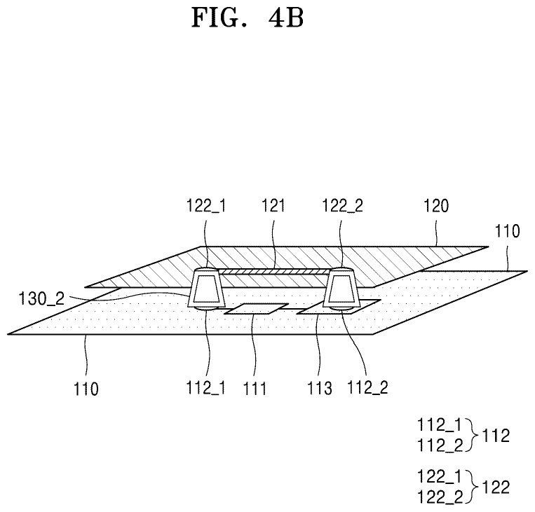

The conductive connection member 130, the first substrate 110, and the second substrate 120 will be described below with reference to FIGS. 4A and 4B.

In an embodiment, electro-magnetic interference (EMI) noise may be generated in the first substrate 110 during operations of the electronic device 100. In detail, during operations of the electronic device 100, the EMI noise may be generated from the at least one processor 111 included in the first substrate 110. The present disclosure is not limited thereto. In FIG. 1, only the at least one processor 111 included in the first substrate 110 is illustrated, but at least one circuit component may be further included in the first substrate 110. Here, during operations of the electronic device 100, EMI noise may be generated from the at least one processor 111 and the at least one circuit component.

In an embodiment, the electronic device 100 may provide, to the conductive line 121 disposed on the second substrate 120 through the at least one processor 111, a compensation signal for reducing the EMI noise generated in the first substrate 110. In an embodiment, a compensation current may flow through the conductive line 121 according to the compensation signal. In an embodiment, the compensation current may be a current flowing through the conductive line 121 according to the compensation signal. When the compensation current flows through the conductive line 121, a magnetic field for reducing the EMI noise generated in the first substrate 110 may be induced from the conductive line 121. The compensation signal may be a signal enabling the compensation current to flow through the conductive line 121 so that the magnetic field for reducing the EMI noise generated in the first substrate 110 is induced.

In an embodiment, the EMI noise generated in the first substrate 110 may be reduced by the magnetic field induced by the compensation current flowing through the conductive line 121. In detail, the EMI noise may be reduced by enabling the compensation current to flow through the conductive line 121 such that the magnetic field is induced in a direction opposite to a direction of the EMI noise generated in the first substrate 110.

In an embodiment, a direction of the compensation signal provided to the conductive line 121 through the at least one processor 111 may be determined according to the direction of the EMI noise generated in the first substrate 110. In an embodiment, a magnitude of the compensation signal provided to the conductive line 121 through the at least one processor 111 may be determined according to a magnitude of the EMI noise generated in the first substrate 110.

In an embodiment, it is described that the at least one processor 111 controls operations of the electronic device 100 and provides the compensation signal to the conductive line 121, but the present disclosure is not limited thereto. In an embodiment, a processor disposed on the first substrate 110 and controlling operations of the electronic device 100, and a processor providing the compensation signal to the conductive line 121 may be different processors. In this case, the generated EMI noise may be reduced by the processor disposed on the first substrate 110 and controlling operations of the electronic device 100, through the magnetic field induced by the compensation current flowing through the conductive line 121 by providing the compensation signal to the conductive line 121. Hereinafter, for convenience of description, it is described that the processor controlling operations of the electronic device 100 and the processor providing the compensation signal to the conductive line 121 are the same processor.

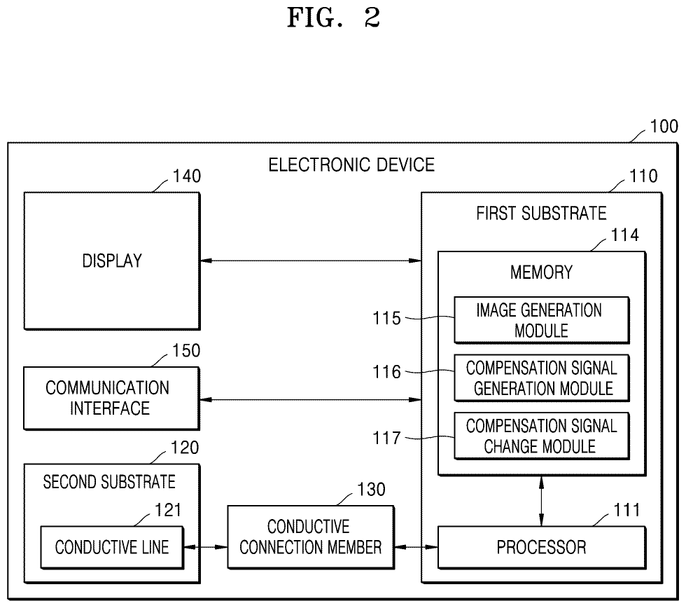

FIG. 2 is a block diagram for describing a configuration of an electronic device, according to an example embodiment.

As shown in FIG. 2, in an embodiment, the electronic device 100 may include a display 140, the first substrate 110, a memory 114, the at least one processor 111, the second substrate 120, the conductive connection member 130, and a communication interface 150. In an embodiment, the memory 114 and the at least one processor 111 may be disposed on the first substrate 110. The conductive line 121 may be disposed on the second substrate 120.

In an embodiment, not all components shown in FIG. 2 are essential. The electronic device 100 may be implemented by more components than those illustrated in FIG. 2 or the electronic device 100 may be implemented by fewer components than those illustrated in FIG. 2.

In an embodiment, the display 140, the first substrate 110, and the communication interface 150 may be connected to each other electrically and/or physically. The display 140, the memory 114, the at least one processor 111, and the communication interface 150 may be connected to each other electrically and/or physically.

In an embodiment, the display 140 and the second substrate 120 may be connected to each other physically. In an embodiment, the first substrate 110 and the second substrate 120 may be connected to each other physically. The first substrate 110 and the second substrate 120 may be connected to each other physically through the conductive connection member 130.

In an embodiment, the at least one processor 111 included in the first substrate 110 and the conductive line 121 included in the second substrate 120 may be connected to each other electrically and/or physically. In an embodiment, the at least one processor 111 included in the first substrate 110 and the conductive line 121 included in the second substrate 120 may be connected to each other electrically and/or physically through the conductive connection member 130.

Hereinafter, same reference numerals are assigned to components that are same as those described with reference to FIG. 1 and descriptions thereof are not provided.

In an embodiment, the display 140 may include any one display from among a liquid crystal display, a plasma display, an organic light-emitting diode display, and an inorganic light-emitting diode display. However, the present disclosure is not limited thereto, and the display 140 may include any type of display capable of providing an image to a user. However, the present disclosure is not limited thereto, and when the electronic device 100 is an electronic device that does not provide an image, the electronic device 100 may not include the display 140.

In an embodiment, the first substrate 110 may include a printed circuit board (PCB). A plurality of circuit components and wires required for operations of the electronic device 100 may be included in the first substrate 110. In an embodiment, the plurality of circuit components may be disposed on the first substrate 110.

In an embodiment, the memory 114 may include at least one type of storage medium among a flash memory type, a hard disk type, a multimedia card micro type, a card type memory (for example, a secure digital (SD) or an extreme digital (XD) memory), a random access memory (RAM), a static RAM (SRAM), a read-only memory (ROM), an electrically erasable programmable ROM (EEPROM), a programmable ROM (PROM), a mask ROM, a flash ROM, a hard disk drive (HDD), and a solid-state drive. The memory 114 may store instructions or program codes for performing functions or operations of the electronic device 100. The instructions, algorithms, data structures, program code, and application programs, which are stored in the memory 114, may be implemented in, for example, a programming or scripting language, such as C, C++, Java, or assembler.

In an embodiment, the memory 114 may store various types of modules that may be used to display an image through the electronic device 100. Also, the memory 114 may store various types of modules that may be used to provide the compensation signal to the conductive line 121 included in the second substrate 120 so as to reduce the EMI noise generated in the first substrate 110 when the electronic device 100 operates.

In an embodiment, the memory 114 may store an image generation module 115, a compensation signal generation module 116, and a compensation signal change module 117. However, not all of the modules shown in FIG. 2 are essential modules. The memory 114 may store more modules than those shown in FIG. 2 or store fewer modules than those shown in FIG. 2.

A “module” included in the memory 114 may denote a unit of processing functions or operations performed by the at least one processor 111. The “module” included in the memory 114 may be realized by instructions, algorithms, data structures, or software such as program code.

In an embodiment, the image generation module 115 may be configured by instructions or program codes related to operations or functions of generating an image to be displayed on the display 140, based on an input image obtained from an external server or other peripheral electronic devices through the communication interface 150.

In an embodiment, the compensation signal generation module 116 may be configured by instructions or program codes related to operations or functions of generating the compensation signal to be provided to the conductive line 121 through the at least one processor 111. In an embodiment, the compensation signal generation module 116 may be configured by instructions or program codes related to operations or functions of generating the compensation signal by determining the direction and the magnitude of the compensation signal to be provided to the conductive line 121, according to the direction and the magnitude of the EMI noise generated in the first substrate 110.

In an embodiment, the direction of the compensation signal may be determined to be a direction in which the magnetic field capable of canceling out the EMI noise generated in the first substrate 110 is induced by the compensation signal flowing through the conductive line 121. In an embodiment, the direction of the magnetic field induced from the conductive line 121 may be determined according to the direction of the compensation signal flowing through the conductive line 121. In an embodiment, according to operations of the electronic device 100, the direction of the compensation signal may be determined such that the direction of the magnetic field induced from the conductive line 121 is opposite to the direction of the EMI noise generated in the first substrate 110.

In an embodiment, the direction of the EMI noise generated in the first substrate 110 according to operations of the electronic device 100 may be a pre-measured direction. In an embodiment, the direction of the EMI noise generated in the first substrate 110 according to operations of the electronic device 100 may be obtained by pre-measuring the direction of EMI noise generated from the at least one processor 111 disposed on the first substrate 110. In an embodiment, when a plurality of circuit components including the at least one processor 111 are included in the first substrate 110, the direction of the EMI noise generated in the first substrate 110 according to operations of the electronic device 100 may be obtained by pre-measuring a direction of the sum of vector components of EMI noise generated in the plurality of circuit components.

In an embodiment, the compensation signal generation module 116 may be configured by instructions or program codes related to operations or functions of generating the compensation signal by determining the direction of the compensation signal, based on the pre-measured direction of the EMI noise generated in the first substrate 110.

In an embodiment, the magnitude of the compensation signal may be determined according to the magnitude of the EMI noise generated in the first substrate 110. In an embodiment, the magnitude of the magnetic field induced from the conductive line 121 through which the compensation signal flows may be determined by the magnitude of the compensation signal. In an embodiment, the magnitude of the magnetic field induced from the conductive line 121 through which the compensation signal flows may be proportional to the magnitude of the compensation signal. In an embodiment, when the magnitude of the EMI noise generated in the first substrate 110 is large, the magnitude of the compensation signal may be determined such that strength of the magnetic field for reducing the EMI noise is increased.

In an embodiment, the magnitude of the EMI noise generated in the first substrate 110 according to operations of the electronic device 100 may be a pre-measured magnitude. In an embodiment, the magnitude of the EMI noise generated in the first substrate 110 according to operations of the electronic device 100 may be obtained by pre-measuring the magnitude of the EMI noise generated from the at least one processor 111 disposed on the first substrate 110. In an embodiment, when the plurality of circuit components including the at least one processor 111 are included in the first substrate 110, the magnitude of the EMI noise generated in the first substrate 110 according to operations of the electronic device 100 may be obtained by pre-measuring the magnitude of the sum of vector components of EMI noise generated in the plurality of circuit components.

In an embodiment, the compensation signal generation module 116 may be configured by instructions or program codes related to operations or functions of generating the compensation signal by determining the magnitude of the compensation signal, based on the pre-measured magnitude of the EMI noise generated in the first substrate 110.

In an embodiment, the direction and the magnitude of the EMI noise generated in the first substrate 110 may be the direction and the magnitude pre-measured in an EMI chamber while the electronic device 100 operates. The pre-measured direction and magnitude of the EMI noise generated in the first substrate 110 may be stored in the memory 114. The at least one processor 111 may generate the compensation signal by applying the pre-measured direction and magnitude of the EMI noise, stored in the memory 114, to the compensation signal generation module 116.

However, the present disclosure is not limited thereto, and the pre-measured direction and magnitude of the EMI noise generated in the first substrate 110 may be stored in an external server or other peripheral electronic devices. The at least one processor 111 may generate the compensation signal by applying, to the compensation signal generation module 116, the pre-measured direction and magnitude of the EMI noise, stored in the external server or the other peripheral electronic device and obtained through the communication interface 150.

The present disclosure is not limited thereto, and the magnitude and the direction of the compensation signal may be pre-set. The at least one processor 111 may generate the compensation signal by applying the pre-set magnitude and direction of the compensation signal to the compensation signal generation module 116. Here, the pre-set magnitude and direction of the compensation signal may be set based on the pre-measured magnitude and direction of the EMI noise.

In an embodiment, the compensation signal change module 117 may be configured by instructions or program codes related to operations or functions of changing at least one of the magnitude and the direction of the compensation signal to be provided to the conductive line 121 through the at least one processor 111. In an embodiment, the compensation signal change module 117 may be configured by instructions or program codes related to operations or functions of changing at least one of the direction and the magnitude of the compensation signal, in response to a change in at least one of the magnitude and the direction of the EMI noise generated in the first substrate 110.

In an embodiment, at least one of the magnitude and the direction of the EMI noise generated in the first substrate 110 may change according to a change in an image displayed on the display 140 by the electronic device 100. In an embodiment, when the resolution of the image displayed on the display 140 is changed or when a pattern of the image, content of the image, or the like is changed, operations of the at least one processor 111 included in the first substrate 110 or the plurality of circuit components included in the at least one processor 111 are changed, and thus, at least one of the magnitude and the direction of the EMI noise generated in the first substrate 110 may be changed. However, the present disclosure is not limited thereto. At least one of the magnitude and the direction of the EMI noise generated in the first substrate 110 may be changed not only when the image displayed on the display 140 is changed, but also when other functions of the electronic device 100 are changed.

In an embodiment, the change in at least one of the magnitude and the direction of the EMI noise generated in the first substrate 110, which is changed according to the change in the image displayed on the display 140 by the electronic device 100, may have been pre-measured. In an embodiment, the magnitude and the direction of the EMI noise generated in the first substrate 110, according to the change in the image displayed on the display 140, may be pre-measured in the EMI chamber.

In an embodiment, the pre-measured change in at least one of the magnitude and the direction of the EMI noise generated in the first substrate 110, according to the change in the image displayed on the display 140, may be stored in the memory 114. In an embodiment, the pre-measured change in at least one of the magnitude and the direction of the EMI noise generated in the first substrate 110, according to the change in the image displayed on the display 140, may be stored in the memory 114 in the form of a lookup table. However, the present disclosure is not limited thereto, and the pre-measured change in at least one of the magnitude and the direction of the EMI noise generated in the first substrate 110, according to the change in the image displayed on the display 140, may be stored in the external server or the other peripheral electronic devices. The pre-measured change in at least one of the magnitude and the direction of the EMI noise generated in the first substrate 110, according to the change in the image displayed on the display 140, may be stored in the external server or the other peripheral electronic devices in the form of a lookup table.

However, the present disclosure is not limited thereto, and the change in at least one of the magnitude and the direction of the EMI noise generated in the first substrate 110, according to the change in other functions of the electronic device 100, may be pre-measured and stored in one of the memory 114, the external server, and the other peripheral electronic devices.

In an embodiment, the at least one processor 111 may change at least one of the magnitude and the direction of the compensation signal by applying, to the compensation signal change module 117, the pre-measured change in at least one of the magnitude and the direction of the EMI noise generated in the first substrate 110, according to the change in the image displayed on the display 140, stored in the memory 114. In an embodiment, the at least one processor 111 may change at least one of the magnitude and the direction of the compensation signal by applying, to the compensation signal change module 117, the lookup table including the change in at least one of the magnitude and the direction of the EMI noise according to the change in the image, stored in the memory 114.

In an embodiment, the at least one processor 111 may change at least one of the magnitude and the direction of the compensation signal by applying, to the compensation signal change module 117, the pre-measured change in at least one of the magnitude and the direction of the EMI noise generated in the first substrate 110, according to the change in the image displayed on the display 140, obtained through the communication interface 150. In an embodiment, the at least one processor 111 may change at least one of the magnitude and the direction of the compensation signal by applying, to the compensation signal change module 117, the lookup table including the change in at least one of the magnitude and the direction of the EMI noise according to the change in the image, obtained through the communication interface 150.

In FIG. 2, the compensation signal generation module 116 and the compensation signal change module 117 are illustrated as separate modules, but the present disclosure is not limited thereto. In an embodiment, the compensation signal generation module 116 and the compensation signal change module 117 may be configured as one module.

In an embodiment, the at least one processor 111 may be configured as at least one of a central processing unit, a microprocessor, a graphics processing unit, an application processor (AP), an application-specific integrated circuit (ASIC), a digital signal processor (DSP), a digital signal processing device (DSPD), a programmable logic device (PLD), a field programmable gate array (FPGS), and an artificial intelligence (AI) dedicated processor designed in a hardware structure specified for training and processing of a neural processing unit or an AI model, but is not limited thereto.

According to an embodiment of the disclosure, the at least one processor 111 may include circuitry, such as a system on chip (SoC) or an integrated circuit (IC). The at least one processor 111 may include a processing circuit.

In an embodiment, the at least one processor 111 may execute various types of modules stored in the memory 114. In an embodiment, the at least one processor 111 may execute the image generation module 115, the compensation signal generation module 116, and the compensation signal change module 117, which are stored in the memory 114. In an embodiment, the at least one processor 111 may execute at least one instruction configuring various types of modules stored in the memory 114.

In an embodiment, the communication interface 150 may perform data communication with an external server according to control by the at least one processor 111. Also, the communication interface 150 may perform data communication with other peripheral electronic devices, in addition to the external server. The communication interface 150 may perform data communication with a server or other peripheral electronic devices by using at least one of data communication methods including, for example, wired local area network (LAN), wireless LAN, Wi-Fi, Bluetooth, ZigBee, Wi-Fi direct (WFD), infrared data association (IrDA), Bluetooth low energy (BLE), near field communication (NFC), wireless broadband Internet (Wibro), world interoperability for microwave access (WiMAX), shared wireless access protocol (SWAP), wireless gigabit alliance (WiGig), and radio frequency (RF) communication.

In an embodiment, the second substrate 120 may include a heat sink. The second substrate 120 may include a heat sink for dissipating heat generated in the first substrate 110. Heat may be generated in the first substrate 110 when the electronic device 100 operates, and the heat generated in the first substrate 110 may be dissipated through the second substrate 120.

However, the present disclosure is not limited thereto. The second substrate 120 may include a substrate for protecting the first substrate 110 from an external impact or a guide plate for guiding a location of the first substrate 110 in the electronic device 100. The second substrate 120 may include a case for accommodating the first substrate 110, the display 140, and the communication interface 150. In other words, a function of the second substrate 120 is not limited.

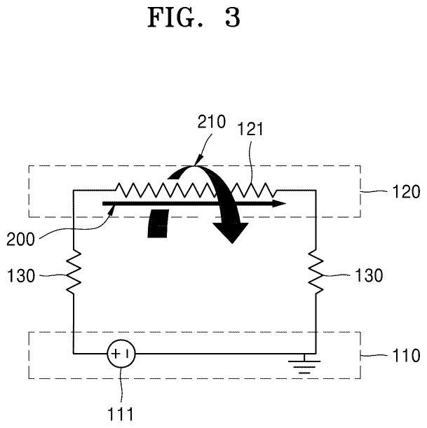

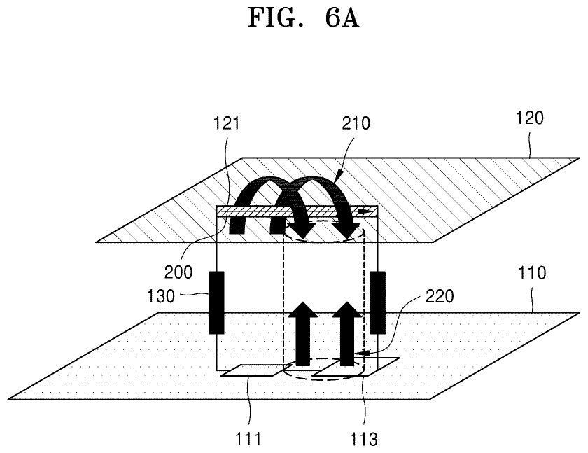

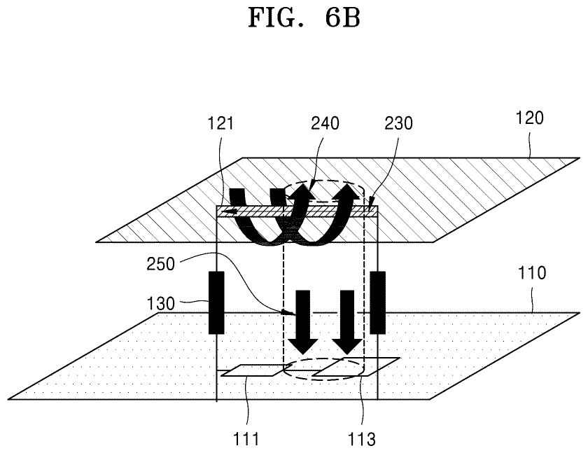

In an embodiment, the conductive line 121 may be disposed on the second substrate 120. The conductive line 121 may include a conductor through which a current may flow. The conductive line 121 may include copper, aluminum, silver, gold, or the like, and is not limited thereto. In an embodiment, a length of the conductive line 121, a cross-sectional area of the conductive line 121, or an arrangement of the conductive line 121 on the second substrate 120 may be determined according to the pre-measured magnitude and direction of the EMI noise generated in the first substrate 110 when the electronic device 100 operates. Hereinafter, the conductive line 121 will be described below with reference to FIGS. 3, 6A, and 6B.

In an embodiment, the conductive connection member 130 may electrically connect the at least one processor 111 disposed on the first substrate 110 to the conductive line 121 disposed on the second substrate 120. Also, the conductive connection member 130 may physically connect the first substrate 110 and the second substrate 120 to each other. In an embodiment, the conductive connection member 130 may include a conductor allowing a current to flow. The conductive line 121 may include copper, aluminum, silver, gold, or the like, and is not limited thereto. In an embodiment, the conductive connection member 130 may include the shape of a fixing pin or a push-pin connecting the first substrate 110 and the second substrate 120 to each other through a via included in the first substrate 110 and a via included in the second substrate 120. The conductive connection member 130 may include the shape of a gasket and may be bonded to the first substrate 110 and the second substrate 120 to connect the first substrate 110 and the second substrate 120 to each other.

FIG. 3 is a diagram for describing an operation of an electronic device, according to an example embodiment. Hereinafter, same reference numerals are assigned to components that are same as those described with reference to FIG. 1 and redundant descriptions are not provided.

Referring to FIGS. 1 and 3, FIG. 3 illustrates an equivalent circuit diagram of the at least one processor 111 disposed on the first substrate 110 and the conductive line 121 disposed on the second substrate 120, wherein the at least one processor 111 and the conductive line 121 are electrically connected to each other by the conductive connection member 130.

In an embodiment, the at least one processor 111 may provide the compensation signal to the conductive line 121 through the conductive connection member 130. In an embodiment, the compensation signal may be a voltage having specific strength and a specific direction. Here, the magnitude and the direction of the compensation signal may be determined by the magnitude and the direction of the EMI noise generated in the first substrate 110.

In an embodiment, a compensation current 200 may flow through the conductive line 121 according to the compensation signal. The magnitude of the compensation current 200 may be determined by the magnitude of resistance of the conductive connection member 130 and the magnitude of resistance of the conductive line 121. In an embodiment, the magnitude of the compensation current 200 may be inversely proportional to the sum of the resistance of the conductive connection member 130 and the resistance of the conductive line 121. However, the present disclosure is not limited thereto, and a relationship between the compensation signal and the compensation current 200 may vary depending on an arrangement of the conductive line 121, the conductive connection member 130, and the at least one processor 111.

In an embodiment, the magnitude of the resistance of the conductive connection member 130 may be determined according to a shape, a type, a material, or the like of the conductive connection member 130. In an embodiment, the magnitude of the resistance of the conductive line 121 may be determined according to the length and the cross-sectional area of the conductive line 121. In an embodiment, the greater the length of the conductive line 121, the greater the magnitude of the resistance of the conductive line 121. The greater the cross-sectional area of the conductive line 121, the smaller the magnitude of the resistance of the conductive line 121.

In FIGS. 1 and 3, the conductive line 121 is illustrated as one line, but the present disclosure is not limited thereto. A plurality of conductive lines may be disposed on the second substrate 120, and in this case, the magnitude of a compensation current may be determined according to equivalent resistance of the plurality of conductive lines.

In an embodiment, when the compensation current 200 flows through the conductive line 121 according to the compensation signal provided by the at least one processor 111, a magnetic field 210 may be induced by the compensation current 200 flowing through the conductive line 121. At this time, the induced magnetic field 210 may be induced in the shape of a concentric circle around the conductive line 121. The strength of the induced magnetic field 210 may be proportional to the strength of the compensation current 200 and inversely proportional to a distance from the conductive line 121. According to a right-handed screw rule, when the compensation current 200 flows in a direction of movement of a right-handed screw, a direction of the induced magnetic field 210 may be a direction of rotation of the right-handed screw.

FIG. 4A is a diagram for describing a conductive connection member according to an example embodiment. Hereinafter, same reference numerals are assigned to components that are same as those described with reference to FIG. 1 and redundant descriptions are not provided.

Referring to FIG. 4A, in an embodiment, the first substrate 110 may include the first hole 112. The first hole 112 may include a first sub-hole 112_1 electrically connected to the at least one processor 111 and a second sub-hole 112_2 electrically connected to the reference voltage electrode 113 of the first substrate 110.

In an embodiment, the second substrate 120 may include the second hole 122 electrically connected to the conductive line 121. In an embodiment, the second hole 122 may include two sub-holes 122_1 and 122_2 electrically connected to opposite ends of the conductive line 121.

In an embodiment, the first substrate 110 and the second substrate 120 may be spaced apart from each other. Referring to FIG. 4A, the first substrate 110 and the second substrate 120 may be spaced apart from each other while being physically connected to each other through a conductive connection member 130_1. The at least one processor 111 included in the first substrate 110 and the conductive line 121 included in the second substrate 120 may be spaced apart from each other while being electrically connected to each other through the conductive connection member 130_1.

However, in FIG. 4A, the first substrate 110 and the second substrate 120 are spaced apart from each other, but the present disclosure is not limited thereto. A portion of the second substrate 120 may protrude in a direction towards the first substrate 110 and another portion thereof may protrude in a direction opposite to the first substrate 110. A distance between the second substrate 120 and the first substrate 110 may vary according to areas where the second substrate 120 and the first substrate 110 overlap each other. In an embodiment, a portion of the second substrate 120 may be in contact with the first substrate 110 and another portion of the second substrate 120 may be spaced apart from the first substrate 110.

In an embodiment, a portion of the second substrate 120 may be in contact with some of the plurality of circuit components disposed on the first substrate 110. In an embodiment, a portion of the second substrate 120, overlapping the at least one processor 111, may be in contact with the at least one processor 111. When the second substrate 120 includes a heat sink, a shape of the second substrate 120 may include a shape in contact with a component that is to dissipate heat from among the plurality of circuit components included in the first substrate 110.

In an embodiment, an adhesive or the like may be disposed between the second substrate 120 and the first substrate 110. The second substrate 120 may be adhered to the first substrate 110 through the adhesive. Here, the adhesive may include a thermal adhesive or the like.

In an embodiment, the first substrate 110 and the second substrate 120 may face each other. However, the present disclosure is not limited thereto, and the first substrate 110 and the second substrate 120 may not face each other, but may be orthogonal to each other or cross each other.

In an embodiment, the conductive connection member 130_1 may electrically connect the first sub-hole 112_1 to the third sub-hole 122_1 electrically connected to one end of the conductive line 121, from among the two sub-holes 122_1 and 122_2 included in the second substrate 120. In an embodiment, the conductive connection member 130_1 may electrically connect the second sub-hole 112_2 to the fourth sub-hole 122_2 electrically connected to another end of the conductive line 121, from among the two sub-holes 122_1 and 122_2 included in the second substrate 120, the fourth sub-hole 122_2 being different from the third sub-hole 122_1.

In an embodiment, the conductive connection member 130_1 may include a fixing pin 131 and a spring 132. In an embodiment, the fixing pin 131 may include the shape of a push-pin. The fixing pin 131 may pass through the first sub-hole 112_1 and the third sub-hole 122_1 and then connect the first substrate 110 and the second substrate 120 to each other as the cross-sectional area of the fixing pin 131 is increased on the first substrate 110 and the second substrate 120. The fixing pin 131 may pass through the second sub-hole 112_2 and the fourth sub-hole 122_2 and then connect the first substrate 110 and the second substrate 120 to each other as the cross-sectional area of the fixing pin 131 is increased on the first substrate 110 and the second substrate 120.

In an embodiment, referring to FIG. 4A, the spring 132 may be disposed between the second hole 122 included in the second substrate 120 and a portion of the fixing pin 131 where the cross-sectional area is increased on the second substrate 120. However, the present disclosure is not limited thereto. In an embodiment, the spring 132 may be disposed between the first hole 112 included in the first substrate 110 and a portion of the fixing pin 131 where the cross-sectional area is increased on the first substrate 110.

When the conductive connection member 130_1 includes the spring 132, the distance between the first substrate 110 and the second substrate 120 may change within a certain range while the first substrate 110 and the second substrate 120 are connected to each other, and thus, the first substrate 110 and the second substrate 120 may be protected from an external impact.

FIG. 4B is a diagram for describing a conductive connection member according to an example embodiment. Hereinafter, same reference numerals are assigned to components that are same as those described with reference to FIG. 4A and redundant descriptions thereof are not provided.

Referring to FIG. 4B, in an embodiment, the first substrate 110 may include the first sub-hole 112_1 electrically connected to the at least one processor 111, and the second sub-hole 112_2 electrically connected to the reference voltage electrode 113 of the first substrate 110. The second substrate 120 may include the third sub-hole 122_1 electrically connected to one end of the conductive line 121, and the fourth sub-hole 122_2 electrically connected to another end of the conductive line 121.

In an embodiment, a conductive connection member 130_2 may electrically connect the first sub-hole 112_1 and the third sub-hole 122_1 to each other. The conductive connection member 130_2 may electrically connect the second sub-hole 112_2 and the fourth sub-hole 122_2 to each other.

In an embodiment, the conductive connection member 130_2 may include a gasket. In an embodiment, the conductive connection member 130_2 may be the gasket 130_2 mounted on a surface of the first substrate 110 and a surface of the second substrate 120. The gasket 130_2 may be mounted on each of a surface of the first sub-hole 112_1 and a surface of the third sub-hole 122_1 to electrically connect the first sub-hole 112_1 and the third sub-hole 122_1 to each other. The gasket 130_2 may be mounted on each of a surface of the second sub-hole 112_2 and a surface of the fourth sub-hole 122_2 to electrically connect the second sub-hole 112_2 and the fourth sub-hole 122_2 to each other.

In an embodiment, the gasket 130_2 may connect the first substrate 110 and the second substrate 120 to each other to maintain the distance between the first substrate 110 and the second substrate 120. In FIG. 4B, two gaskets 130_2 are illustrated, but the present disclosure is not limited thereto. In an embodiment, the gasket 130_2 may be mounted on areas of a surface of the first substrate 110 and a surface of the second substrate 120, other than the first to fourth sub-holes 112_1, 112_2, 122_1, and 122_2 to maintain the distance between the first substrate 110 and the second substrate 120 while connecting the first substrate 110 and the second substrate 120 to each other.

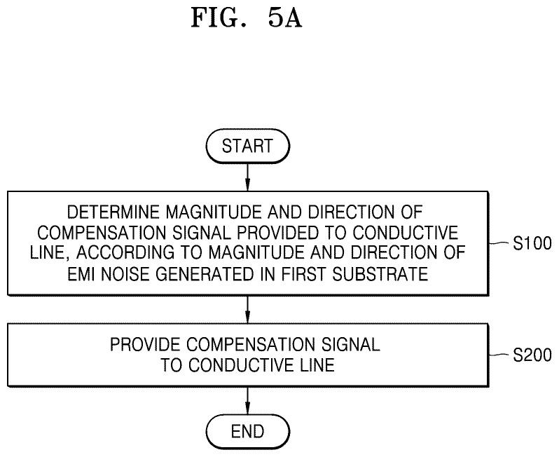

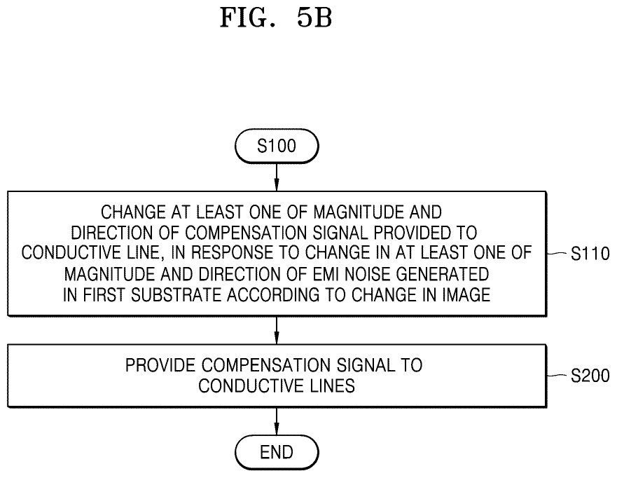

FIG. 5A is a flowchart for describing an operation in which an electronic device determines a magnitude and a direction of a compensation signal, according to an example embodiment.

Referring to FIGS. 1, 2, and 5A, an operating method of the electronic device 100 may include determining the magnitude and the direction of the compensation signal provided to the conductive line 121 according to the magnitude and the direction of the EMI noise generated in the first substrate 110, during operations of the electronic device 100 (S100).

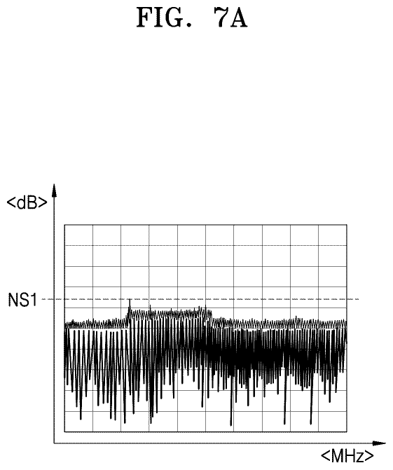

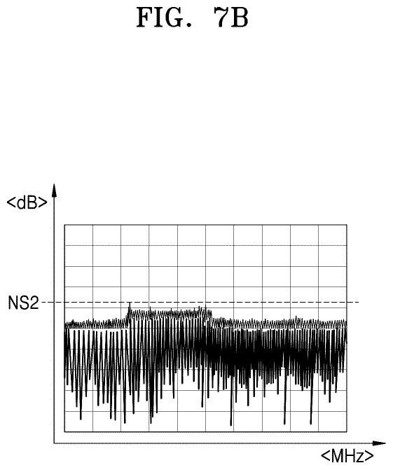

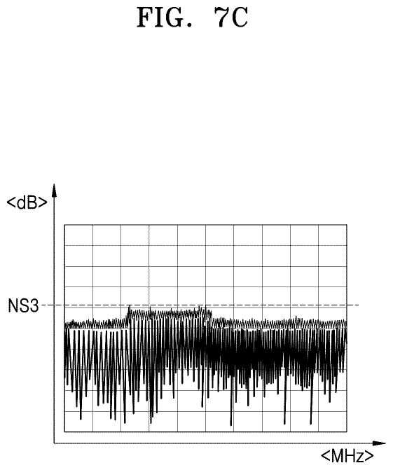

In an embodiment, in the determining of the magnitude and the direction of the compensation signal (S100), the at least one processor 111 may determine the magnitude and the direction of the compensation signal by executing the compensation signal generation module 116. In an embodiment, the at least one processor 111 may determine the magnitude and the direction of the compensation signal by applying, to the compensation signal generation module 116, the pre-measured magnitude and direction of the EMI noise generated in the first substrate 110. Hereinafter, an operation of determining the magnitude and the direction of the compensation signal will be described in detail with reference to FIGS. 6A to 7C.

In an embodiment, the operating method of the electronic device 100 may include providing the compensation signal having the determined magnitude and direction to the conductive line 121 (S200).

In an embodiment, the operating method of the electronic device 100 may include controlling operations of the electronic device 100 through the at least one processor 111 included in the first substrate 110. In an embodiment, the controlling of the operations of the electronic device 100 through the at least one processor 111 and the providing of the compensation signal to the conductive line 121 (S200) may be performed together. Accordingly, during the controlling of the operations of the electronic device 100 through the at least one processor 111, the EMI noise generated in the first substrate 110 may be reduced by a magnetic field induced by the compensation signal flowing through the conductive line 121. Accordingly, occurrence of malfunction or heat generation of the electronic device 100, caused by the EMI noise generated in the first substrate 110, may be prevented or reduced during operations of the electronic device 100.

FIG. 5B is a flowchart for describing an operation in which an electronic device changes at least one of a magnitude and a direction of a compensation signal, according to an example embodiment. Hereinafter, same reference numerals are assigned to operations that are same as those described with reference to FIG. 5A and redundant descriptions thereof are not provided.

Referring to FIGS. 1, 2, 5A, and 5B, the operating method of the electronic device 100 may include, after the determining of the magnitude and the direction of the compensation signal (S100), changing at least one of the magnitude and the direction of the compensation signal provided to the conductive line 121, in response to a change in at least one of the magnitude and the direction of the EMI noise generated in the first substrate 110 according to a change in an image (S110).

In an embodiment, in the changing of at least one of the magnitude and the direction of the compensation signal (S110), the at least one processor 111 may change at least one of the magnitude and the direction of the compensation signal by executing the compensation signal change module 117. In an embodiment, the at least one processor 111 may change at least one of the magnitude and the direction of the compensation signal by applying, to the compensation signal change module 117, the change in the pre-measured magnitude and direction of the EMI noise according to the change in the image. However, the present disclosure is not limited thereto. The determining of the magnitude and the direction of the compensation signal (S100) and the changing of the magnitude and the direction of the compensation signal (S110) may be performed through one operation.

Hereinafter, an operation of changing at least one of the magnitude and the direction of the compensation signal will be described in detail with reference to FIGS. 6A to 7C.

FIG. 6A is a diagram for describing a direction of a magnetic field induced from a conductive line, according to an arrangement of the conductive line and a direction of a compensation signal, according to an example embodiment. Hereinafter, same reference numerals are assigned to components that are same as those described with reference to FIGS. 1 and 3, and redundant descriptions are not provided.

Referring to FIG. 6A, a pattern of the conductive line 121 disposed on the second substrate 120 may be determined according to the EMI noise generated in the first substrate 110. Here, the pattern of the conductive line 121 may include a location of the conductive line 121 on the second substrate 120, the length of the conductive line 121, the thickness of the conductive line 121, and the number of conductive lines 121. In an embodiment, the magnetic field 210 induced by the compensation current 200 flowing through the conductive line 121 may include the shape of a concentric circle around the conductive line 121. Accordingly, the pattern of the conductive line 121 may be determined such that a magnetic field capable of reducing the EMI noise generated in the first substrate 110 is induced.

Here, the EMI noise generated in the first substrate 110 according to operations of the electronic device 100 may be pre-measured. An area of the first substrate 110 where the EMI noise is generated may be calculated according to the pre-measured EMI noise. The pattern of the conductive line 121 may be determined such that a magnetic field for reducing the EMI noise is induced in the area of the first substrate 110 where the EMI noise is generated. Here, the conductive line 121 may be disposed on the second substrate 120 in the pattern determined through the calculation.

In an embodiment, the direction of the compensation signal provided to the conductive line 121 by the at least one processor 111 may be determined according to a direction 220 of the EMI noise generated in the first substrate 110.

In an embodiment, the direction 220 of the EMI noise generated in the first substrate 110 may be a direction of the sum of vector components of EMI noise generated in the plurality of circuit components including the at least one processor 111 disposed on the first substrate 110.

In an embodiment, the at least one processor 111 may determine the direction of the compensation signal such that the direction 220 of the EMI noise is opposite to the direction of the magnetic field 210 induced by the compensation current 200 flowing through the conductive line 121, in the area of the first substrate 110 where the EMI noise is generated.

In an embodiment, when the direction of the EMI noise generated in the first substrate 110 is measured to face a top surface of the first substrate 110 in a specific area of the first substrate 110, the at least one processor 111 may determine the direction of the compensation signal such that the magnetic field 210 for reducing the EMI noise is induced in a direction facing a bottom surface of the first substrate 110.

Here, the conductive line 121 may be disposed on the second substrate 120 in the pattern determined such that a magnetic field for reducing the EMI noise is induced in the area of the first substrate 110 where the EMI noise is generated. Accordingly, the at least one processor 111 may determine the direction of the compensation signal provided to the conductive line 121 to control a magnetic field for reducing the EMI noise facing the top surface of the first substrate 110 to be induced from the compensation current 200 flowing through the conductive line 121.

FIG. 6B is a diagram for describing a direction of a magnetic field induced from a conductive line, according to an arrangement of the conductive line and a direction of a compensation signal, according to an example embodiment. Hereinafter, same reference numerals are assigned to components that are same as those described with reference to FIGS. 1, 3, and 6A and redundant descriptions thereof are not provided.

In an embodiment, when the direction of the EMI noise generated in the first substrate 110 is measured to face the bottom surface of the first substrate 110 in a specific area of the first substrate 110, the at least one processor 111 may determine the direction of the compensation signal such that a magnetic field 240 for reducing the EMI noise is induced in a direction facing the top surface of the first substrate 110.

In an embodiment, the at least one processor 111 may determine the direction of the compensation signal provided to the conductive line 121 to control a magnetic field for reducing the EMI noise facing the bottom surface of the first substrate 110 to be induced from a compensation current 230 flowing through the conductive line 121.

FIG. 7A is a diagram for describing a degree of reduction of EMI noise according to magnitude of a compensation signal, according to an example embodiment. FIG. 7B is a diagram for describing a degree of reduction of EMI noise according to magnitude of a compensation signal, according to an example embodiment. FIG. 7C is a diagram for describing a degree of reduction of EMI noise according to magnitude of a compensation signal, according to an example embodiment.

Referring to FIGS. 1, 2, and 7A, FIG. 7A illustrates a waveform of the EMI noise generated in the first substrate 110 in case that a compensation signal is not provided to the conductive line 121 through the at least one processor 111 during operations of the electronic device 100. Here, an x-axis denotes a driving frequency of the at least one processor 111 in units of megahertz (MHz). A y-axis denotes the magnitude of the EMI noise in units of decibel (dB). However, the present disclosure is not limited thereto, and units of the x-axis and the y-axis may vary according to operations of the electronic device 100.

The waveform of the EMI noise illustrated in FIG. 7A may have a first magnitude NS1. The first magnitude NS1 may be a magnitude in which the EMI noise is not reduced by a magnetic field induced by a compensation current flowing through the conductive line 121, according to the present disclosure.

Referring to FIGS. 1, 2, and 7B, FIG. 7B illustrates a waveform of the EMI noise generated in the first substrate 110 in case that a compensation signal having a first compensation magnitude is provided to the conductive line 121 through the at least one processor 111 during operations of the electronic device 100.

The waveform of the EMI noise illustrated in FIG. 7B may have a second magnitude NS2. The second magnitude NS2 may be a magnitude of the EMI noise generated in the first substrate 110, which has been reduced by a magnetic field induced by the conductive line 121, in case that the compensation signal having the first compensation magnitude is provided to the conductive line 121 through the at least one processor 111. In an embodiment, the second magnitude NS2 may be less than the first magnitude NS1. Accordingly, the EMI noise generated in the first substrate 110 may be reduced through a magnetic field induced providing the compensation signal through the at least one processor 111 to the conductive line 121 electrically connected to the at least one processor 111, according to the present disclosure.

Referring to FIGS. 1, 2, and 7C, FIG. 7C illustrates a waveform of the EMI noise generated in the first substrate 110 in case that a compensation signal having a second compensation magnitude is provided to the conductive line 121 through the at least one processor 111 during operations of the electronic device 100. In an embodiment, the second compensation magnitude may be greater than the first compensation magnitude.

The waveform of the EMI noise illustrated in FIG. 7C may have a third magnitude NS3. The third magnitude NS3 may be a magnitude of the EMI noise generated in the first substrate 110, which has been reduced by a magnetic field induced by the conductive line 121, in case that the compensation signal having the second compensation magnitude is provided to the conductive line 121 through the at least one processor 111. In an embodiment, the third magnitude NS3 may be less than the second magnitude NS2. Accordingly, when a magnitude of the compensation signal provided to the conductive line 121 through the at least one processor 111 is great, an effect of reducing the EMI noise generated in the first substrate 110 may be high.

However, when the magnitude of the compensation signal provided to the conductive line 121 by the at least one processor 111 is great, power consumption of the at least one processor 111 may be high. Also, when the magnitude of the compensation signal flowing through the conductive line 121 according to the compensation signal is great, heat generated in the second substrate 120 including the conductive line 121 may be high. In addition, when the magnitude of the compensation signal flowing through the conductive line 121 according to the compensation signal is great, EMI noise may be generated in the second substrate 120 including the conductive line 121, thereby affecting operations of the electronic device 100.

Accordingly, the magnitude of a compensation signal provided to the conductive line 121 by the at least one processor 111 may be determined appropriately in consideration of at least one of the magnitude of the EMI noise generated in the first substrate 110, the power consumption of the at least one processor 111, the heat generated in the second substrate 120, and the EMI noise generated in the second substrate 120.

According to an embodiment, an electronic device is provided. The electronic device may include a first substrate. The electronic device may include a memory storing at least one instruction and disposed on the first substrate. The electronic device may include at least one processor configured to execute the at least one instruction stored in the memory and disposed on the first substrate. The electronic device may include a second substrate on which a conductive line is disposed. The at least one processor and the conductive line may be electrically connected to each other. The at least one processor may be further configured to provide a compensation signal to the conductive line so that a magnetic field for reducing electro-magnetic interference (EMI) noise generated in the first substrate is induced from the conductive line.

In an embodiment, the first substrate and the second substrate may be spaced apart from each other.

In an embodiment, the first substrate and the second substrate may face each other.

In an embodiment, the at least one processor and the conductive line may be electrically connected to each other through a conductive connection member connecting the first substrate and the second substrate to each other.

In an embodiment, the second substrate may include a heat sink that dissipates heat generated in the first substrate.

In an embodiment, the EMI noise generated in the first substrate may be pre-measured. The conductive line may be disposed on the second substrate in a pattern calculated so that the magnetic field for reducing the pre-measured EMI noise is induced.

In an embodiment, a magnitude and a direction of the magnetic field induced from the conductive line may be determined according to a magnitude and a direction of the compensation signal provided to the conductive line. The at least one processor may be further configured to determine the magnitude and the direction of the compensation signal provided to the conductive line according to a magnitude and a direction of the EMI noise generated in the first substrate.

In an embodiment, the electronic device may further include a display displaying an image. The at least one processor may be further configured to change at least one of the magnitude and the direction of the compensation signal provided to the conductive line, based on a change in at least one of the magnitude and the direction of the EMI noise generated in the first substrate according to a change in the image displayed through the display.

In an embodiment, the direction of the magnetic field induced from the conductive line may be opposite to the direction of the EMI noise generated in the first substrate.

In an embodiment, the magnitude of the compensation signal may be determined in consideration of at least one of the magnitude of the EMI noise generated in the first substrate, power consumption of the at least one processor, heat generated in the second substrate, and EMI noise generated in the second substrate.

According to an embodiment, an operating method of an electronic device is provided. The electronic device may include a first substrate on which at least one processor is disposed, and a second substrate on which a conductive line electrically connected to the at least one processor is disposed. The operating method may include providing a compensation signal to the conductive line so that a magnetic field for reducing electro-magnetic interference (EMI) noise generated in the first substrate is induced from the conductive line.

In an embodiment, a magnitude and a direction of the magnetic field induced from the conductive line may be determined according to a magnitude and a direction of the compensation signal provided to the conductive line. The operating method may further include determining the magnitude and the direction of the compensation signal provided to the conductive line according to a magnitude and a direction of the EMI noise generated in the first substrate.

In an embodiment, the electronic device may further include a display displaying an image. The operating method may further include changing at least one of the magnitude and the direction of the compensation signal provided to the conductive line, based on a change in at least one of the magnitude and the direction of the EMI noise generated in the first substrate according to a change in the image displayed through the display.

In an embodiment, the magnitude of the compensation signal may be determined in consideration of at least one of the magnitude of the EMI noise generated in the first substrate, power consumption of the at least one processor, heat generated in the second substrate, and EMI noise generated in the second substrate.

According to an embodiment, an electronic device for displaying an image is provided. The electronic device may include a display displaying the image. The electronic device may include a first substrate on which a memory storing at least one instruction and at least one processor configured to execute the at least one instruction stored in the memory are disposed. The electronic device may include a second substrate spaced apart from the first substrate and on which a conductive line is disposed. The at least one processor and the conductive line may be electrically connected to each other. The at least one processor may be further configured to control the display to display the image. The at least one processor may be further configured to provide a compensation signal to the conductive line so that a magnetic field for reducing electro-magnetic interference (EMI) noise generated in the first substrate is induced from the conductive line. “On which” as used herein covers both disposed directly on as well as disposed indirectly on.

According to an example embodiment, provided is a computer-readable recording medium having recorded thereon a program for executing, on a computer, at least one method among embodiments of the methods.

A program executed by an electronic device described in the present disclosure may be implemented by a hardware component, a software component, and/or a combination of a hardware component and a software component. The program may be performed by any system capable of performing computer-readable instructions.

Software may include a computer program, a code, an instruction, or a combination thereof, and may configure the processing device to operate as desired or instruct the processing device independently or collectively.

The software may be implemented as a computer program that includes instructions stored on computer-readable storage media. Examples of computer-readable recording medium include magnetic storage media (for example, read-only memory (ROM), random-access memory (RAM), floppy disc, and hard disc) and optical reading media (for example, CD-ROM and digital versatile disk (DVD). The computer-readable recording medium may be distributed over a computer system connected through a network, and computer-readable codes may be stored and executed in a distributed manner. The recording medium is readable by a computer, stored in a memory, and may be executed in a processor.

A computer-readable storage medium may be provided in the form of a non-transitory storage medium. Here, the “non-transitory storage medium” only denotes a tangible device and does not contain a signal (for example, electromagnetic waves). This term does not distinguish a case where data is stored in the storage medium semi-permanently and a case where the data is stored in the storage medium temporarily. For example, the “non-transitory storage medium” may include a buffer where data is temporarily stored.

Furthermore, a program according to the embodiments of the present specification may be provided by being included in a computer program product. The computer program products are products that can be traded between sellers and buyers.

The computer program product may include a software program or a computer-readable storage medium storing a software program. For example, the computer program product may include a product in the form of a software program (e.g., a downloadable application) that is distributed electronically by a manufacturer of an electronic device or through an electronic market (e.g., Samsung Galaxy Store). For electronic distribution, at least a part of the software program may be stored in a storage medium or may be temporarily generated. In this case, the storage medium may be a storage medium of a server of a manufacturer of an electronic device, a server of an electronic market, or a relay server that temporarily stores the software program.

As above, embodiments have been described by the limited examples and drawings, but various changes and modifications are possible from the above description by one of ordinary skill in the art. For example, appropriate results may be achieved even when the described techniques are performed in an order different from the described method, and/or components, such as computer systems or modules, are combined or associated in a form different from the described method, or replaced by other components or equivalents.

1. An electronic device comprising:
a first substrate;
a memory storing at least one instruction and disposed on the first substrate;
at least one processor, comprising processing circuitry, configured to individually and/or collectively execute the at least one instruction stored in the memory and disposed on the first substrate; and
a second substrate on which a conductive line is disposed,
wherein the at least one processor and the conductive line are electrically connected to each other, and
the at least one processor is individually and/or collectively configured to:
provide a compensation signal to the conductive line so that a magnetic field for reducing electro-magnetic interference (EMI) noise generated in the first substrate is induced from the conductive line.

2. The electronic device of claim 1, wherein
the first substrate and the second substrate are spaced apart from each other.

3. The electronic device of claim 1, wherein
the first substrate and the second substrate face each other.

4. The electronic device of claim 1, wherein
the at least one processor and the conductive line are electrically connected to each other through at least a conductive connection member connecting the first substrate and the second substrate to each other.

5. The electronic device of claim 1, wherein
the second substrate comprises a heat sink that is configured to dissipate heat generated in the first substrate.

6. The electronic device of claim 1, wherein
the EMI noise generated in the first substrate is pre-measured, and the conductive line is disposed on the second substrate in a pattern so that the magnetic field for reducing the pre-measured EMI noise is induced.

7. The electronic device of claim 1, wherein
a magnitude and a direction of the magnetic field induced from the conductive line are based on a magnitude and a direction of the compensation signal provided to the conductive line, and
the at least one processor is individually and/or collectively configured to determine the magnitude and the direction of the compensation signal provided to the conductive line based on a magnitude and a direction of the EMI noise generated in the first substrate.

8. The electronic device of claim 7, further comprising
a display for displaying an image,
wherein the at least one processor is individually and/or collectively configured to
change at least one of the magnitude and/or the direction of the compensation signal provided to the conductive line, based on a change in at least one of the magnitude and the direction of the EMI noise generated in the first substrate based on a change in the image displayed through the display.

9. The electronic device of claim 7, wherein
the direction of the magnetic field induced from the conductive line is opposite to the direction of the EMI noise generated in the first substrate.

10. The electronic device of claim 1, wherein
the magnitude of the compensation signal is determined based on at least one of the magnitude of the EMI noise generated in the first substrate, power consumption of the at least one processor, heat generated in the second substrate, and EMI noise generated in the second substrate.

11. An operating method of an electronic device, wherein
the electronic device comprises a first substrate on which at least one processor is disposed, and a second substrate on which a conductive line electrically connected to the at least one processor is disposed,
the operating method comprising providing a compensation signal to the conductive line so that a magnetic field for reducing electro-magnetic interference (EMI) noise generated in the first substrate is induced from the conductive line.

12. The operating method of claim 11, wherein
the first substrate and the second substrate are spaced apart from each other.

13. The operating method of claim 11, wherein
the first substrate and the second substrate face each other.

14. The operating method of claim 11, wherein
the at least one processor and the conductive line are electrically connected to each other through at least a conductive connection member connecting the first substrate and the second substrate to each other.

15. The operating method of claim 11, wherein
the second substrate comprises a heat sink that is configured to dissipate heat generated in the first substrate.

16. The operating method of claim 11, wherein
the EMI noise generated in the first substrate is pre-measured, and the conductive line is disposed on the second substrate in a pattern so that the magnetic field for reducing the pre-measured EMI noise is induced.

17. The operating method of claim 11, wherein
a magnitude and a direction of the magnetic field induced from the conductive line are based on a magnitude and a direction of the compensation signal provided to the conductive line, and
the operating method further comprising
determining the magnitude and the direction of the compensation signal provided to the conductive line according to a magnitude and a direction of the EMI noise generated in the first substrate.

18. The operating method of claim 17, wherein
the electronic device further comprises a display for displaying an image, and
the operating method further comprising
changing at least one of the magnitude and the direction of the compensation signal provided to the conductive line, based on a change in at least one of the magnitude and the direction of the EMI noise generated in the first substrate according to a change in the image displayed through the display.

19. The operating method of claim 11, wherein
the magnitude of the compensation signal is determined based on at least one of the magnitude of the EMI noise generated in the first substrate, power consumption of the at least one processor, heat generated in the second substrate, and EMI noise generated in the second substrate.

20. An electronic device for displaying an image, the electronic device comprising:
a display configured for displaying the image;
a first substrate on which a memory storing at least one instruction and at least one processor configured to execute the at least one instruction stored in the memory are disposed; and
a second substrate spaced apart from the first substrate and on which a conductive line is disposed,
wherein the at least one processor and the conductive line are electrically connected to each other, and
the at least one processor is individually and/or collectively configured to:
control the display to display the image; and
provide a compensation signal to the conductive line so that a magnetic field for reducing electro-magnetic interference (EMI) noise generated in the first substrate is induced from the conductive line.
